(19) United States
(12) Patent Application Publication
(10) Pub. No.: US 2008/0273629 A1
(43) Pub. Date: Nov. 6, 2008

(54) UWB RECEIVER DESIGNS BASED ON A GAUSSIAN-LAPLACIAN NOISE-PLUS-MAI MODEL

(76) Inventor: Norman C. BEAULIEU, Edmonton (CA)

Correspondence Address: SMART & BIGGAR;P.O. BOX 2999, STATION D, 900-55 METCALFE STREET, OTTAWA, ON, K1P5Y6, CA

(21) Appl. No.: 12/114,321

(22) Filed: May 2, 2008

Related U.S. Application Data
(60) Provisional application No. 60/915,502, filed on May 2, 2007.

(51) Int. Cl. H04L 27/06; H03D 1/00

(52) U.S. Cl. 375/340

(57) ABSTRACT

Two novel receiver structures which surpass the performance of the conventional matched filter receiver are proposed for ultra-wide bandwidth multiple access communications. The proposed receiver structures are derived based on a more appropriate statistical model for the multiple access interference than the generally used Gaussian approximation.

### RELATED APPLICATION

This application claims the benefit of U.S. Provisional Application No. 60/915,502 filed May 2, 2007 hereby incorporated by reference in its entirety.

### FIELD OF THE INVENTION

The invention relates to receivers and methods for performing reception of UWB (ultra-wide bandwidth) signals.

### BACKGROUND OF THE INVENTION

Ultra-wide bandwidth (UWB) communication is a promising technique for high speed indoor and outdoor wireless communication. The time-hopping (TH) technique, the direct sequence (DS) technique and hybrid techniques using both TH and DS coding have been proposed as multiple access techniques for multi-user UWB systems. Despite the differences in the multiple access techniques, the single user correlation receiver is the widely adopted receiver for UWB signal detection. A correlation receiver is optimal if the detection problem is that of detecting a known signal in additive Gaussian noise. The correlation receiver for UWB will not be an optimal receiver unless the multiple access interference component in the decision metric can be accurately approximated as Gaussian.

It is evident from reported results that the distribution of the multiple access interference (MAI) in both TH and DS UWB systems cannot be accurately approximated by a Gaussian distribution for some values of signal-to-noise ratio (SNR) and signal-to-interference ratio (SIR). See G. Durisi and G. Romano, “On the validity of Gaussian approximation to characterize the multiuser capacity of UWB TH PPM,” in Proc. IEEE Ultra Wideband Syst. Technol., May 2002, pp. 157-161, A. R. Forouzan, M. Nasiri-Kenari, and J. A. Salehi, “Performance analysis of time-hopping spread-spectrum multiple-access systems: uncoded and coded schemes,” IEEE Trans. Wireless Commun., vol. 1, pp. 671-681, October 2002 and K. A. Hamdi and X. Gu, “On the validity of the Gaussian approximation for performance analysis of TH-CDMA/OOK impulse radio networks,” in Proc. IEEE Veh. Technol. Conf., April 2003, pp. 2211-2215. Performance evaluation results in the above references show that a Gaussian approximation (GA) to the MAI significantly under estimates the bit error rate (BER) of a UWB system.

Since the MAI is not Gaussian distributed one expects that one can find an improved receiver structure by finding a better statistical model for the MAI. Different models have been proposed for the MAI in various UWB multiple access systems in the context of BER calculation, but the use of these models to derive an optimum (maximal likelihood) receiver seems difficult due to the complexity of the models. Meanwhile, the performance of multi-user UWB systems is significantly degraded by MAI. Therefore, it is of interest to develop improved UWB receiver structures which can perform better in multiple access environments. One of the known solutions to this problem is multi-user detection (MUD). However, MUD is not an attractive candidate for UWB wireless communication devices since implementing MUD algorithms, which are generally computationally intense by nature, on a low power wireless hand-held receiver may not be economical.

### SUMMARY OF THE INVENTION

According to one broad aspect, the invention provides a method of receiving comprising: receiving a signal over a wireless channel; for each of a plurality N of observations of a symbol contained in the signal, using a receiver based on a Gaussian-noise plus Laplacian multi-access interference (MAI) assumption for the wireless channel to produce a respective partial decision statistic; summing the partial decision statistics to produce a sum and making a decision on the symbol contained in the signal based on the sum; outputting the decision.

In some embodiments, for each of a plurality N of observations of a symbol contained in the signal, using a receiver based on a Gaussian-noise plus Laplacian multi-access interference (MAI) assumption for the wireless channel to produce a respective partial decision statistic comprises: using a receiver model that is optimal based on the Gaussian noise plus Laplacian MAI assumption for the wireless channel.

In some embodiments, for each of a plurality N of observations of a symbol contained in the signal, using a receiver based on a Gaussian-noise plus Laplacian multi-access interference (MAI) assumption for the wireless channel to produce a respective partial decision statistic comprises: using a piecewise linear approximation to a receiver model that is optimal based on the Gaussian noise plus Laplacian MAI assumption for the wireless channel.

In some embodiments, using a piecewise linear approximation comprises: using a first limit value of the optimal receiver model above a first threshold; using a second limit value of the optimal receiver below a second threshold; using a straight line tangent to the optimal receiver at the origin between the first threshold and the second threshold.

In some embodiments, receiving a signal comprises receiving a signal having a signal bandwidth that is greater than 20% of the carrier frequency, or receiving a signal having a signal bandwidth greater than 500 MHz.

In some embodiments, receiving a signal comprises receiving a signal having a signal bandwidth greater than 15% of the carrier frequency.

In some embodiments, receiving a signal comprises receiving a signal having pulses that are 1 ns in duration or shorter.

In some embodiments, receiving a signal comprises receiving a UWB signal.

In some embodiments, receiving a signal comprises receiving a TH UWB signal.

In some embodiments, receiving a signal comprises receiving a DS UWB signal.

In some embodiments, the method further comprises: determining the plurality N of observations by determining an observation vector [γ_{0,b}, . . . , γ_{N}_{ₛ}_{1,b}] containing a set of correlations; wherein each partial decision statistic is gₒₚₜ(γ_{i,b}) and is determined according to

$${g}_{opt} ( γ ) = ln [ \frac{exp ( \frac{γ - s}{\hat{c}} ) Q ( \frac{γ - s + {σ}^{2} / \tilde{c}}{σ} ) + exp ( - \frac{γ - s}{\tilde{c}} ) Q ( \frac{- γ + s + {σ}^{2} / \tilde{c}}{σ} )}{exp ( \frac{γ + s}{\tilde{c}} ) Q ( \frac{γ + s + {σ}^{2} / \tilde{c}}{σ} ) + exp ( - \frac{γ + s}{\tilde{c}} ) Q ( \frac{- γ - s + {σ}^{2} / \tilde{c}}{σ} )} ]$$

determined for γ=γ_{i,b} of the observation vector [γ_{0,b}, . . . , γ_{N}_{ₛ}_{1,b}] where: σᵢ²=σ²=E{nᵢ²}=N₀/2, is the noise variance, 2\tilde{c}²=E{I²} is the variance of the MAI; Q(·) is the standard Gaussian Q-function; s is a desired signal component at the receiver; and wherein the sum is determined according to

$$Λ ( γ ) = {\sum }_{i = 0}^{{N}_{s} - 1} {g}_{opt} ( {γ}_{i , b} )$$

and the decision rule for binary signalling in detecting the b^{th} symbol is given by Λ(γ)<0 [symbol] −1 and Λ(γ)>0 [symbol] 1.

In some embodiments, the method further comprises: determining the plurality N of observations by determining an observation vector containing a set of correlations; wherein each partial decision statistic is gₗₐ(γ_{i,b}) and is determined according to

$${g}_{la} ( γ ) = \vert \frac{m γ}{2} + \frac{2}{\tilde{c}} \vert - \vert \frac{m γ}{2} - \frac{s}{\tilde{c}} \vert$$

determined for γ=γ_{i,b} of the observation vector [γ_{0,b}, . . . , γ_{N}_{ₛ}_{1,b}] where: 2\tilde{c}²=E{I²} is the variance of the MAI; m is the slope of the tangent; and wherein the sum is determined according to

$$\tilde{Λ} ( γ ) = {\sum }_{i = 0}^{{N}_{s} - 1} {g}_{la} ( {γ}_{i , b} )$$

and the decision rule for binary signalling in detecting the b^{th} symbol is given by \tilde{Λ}(γ)<0 [symbol] −1 and \tilde{Λ}(γ)>0 [symbol] 1.

According to another broad aspect, the invention provides a receiver comprising: at least one antenna for receiving a signal over a wireless channel; a correlator that generates a plurality of partial correlations from the signal received via the at least one antenna; a partial statistic generator that generates a respective partial statistic for each partial correlation based on a Gaussian-noise plus Laplacian multi-access interference (MAI) assumption for the wireless channel to produce a respective partial decision statistic; an accumulator that accumulates the partial statistics to produce a sum; a threshold function that makes a decision based on the sum and outputs the decision.

In some embodiments, the partial statistic generator generates the respective partial statistic using an optimal nonlinearity function.

In some embodiments, the partial statistic generator generates the respective partial statistic using a nonlinearity function that is a piecewise approximation to an optimal nonlinearity function.

In some embodiments, the partial statistic generator is configured to use a piecewise approximation by: using a first limit value of the optimal receiver model above a first threshold; using a second limit value of the optimal receiver below a second threshold; using a straight line tangent to the optimal receiver at the origin between the first threshold and the second threshold.

In some embodiments, the partial statistic generator generates each partial decision statistic is gₒₚₜ(γ_{i,b}) and is determined according to

$${g}_{opt} ( γ ) = ln [ \frac{exp ( \frac{γ - s}{\tilde{c}} ) Q ( \frac{γ - s + {σ}^{2} / \tilde{c}}{σ} ) + exp ( - \frac{γ - s}{\tilde{c}} ) Q ( \frac{- γ + s + {σ}^{2} / \tilde{c}}{σ} )}{exp ( \frac{γ + s}{\tilde{c}} ) Q ( \frac{γ + s + {σ}^{2} / \tilde{c}}{σ} ) + exp ( - \frac{γ + s}{\tilde{c}} ) Q ( \frac{- γ - s + {σ}^{2} / \tilde{c}}{σ} )} ]$$

determined for γ=γ_{i,b} where γ is the observation vector [γ_{0,b}, . . . , γ_{N}_{ₛ}_{1,b}] containing a set of correlations, where: σᵢ²=σ²=E{nᵢ²}=N₀/2, is the noise variance, 2c²=E{I²} is the variance of the MAI; Q(·) is the standard Gaussian Q-function; s is a desired signal component at the receiver; wherein the accumulator determines the sum according to

$$Λ ( γ ) = {\sum }_{i = 0}^{{N}_{s} - 1} {g}_{opt} ( {γ}_{i , b} ) ;$$

and wherein the threshold function implements a decision rule for binary signalling in detecting the b^{th} symbol according to

Λ(γ)<0 [symbol] −1 and Λ(γ)>0 [symbol] 1.

In some embodiments, the partial statistic generator generates each partial decision statistic gₗₐ(γ_{i,b}) according to

$${g}_{la} ( γ ) = \vert \frac{m γ}{2} + \frac{s}{\tilde{c}} \vert - \vert \frac{m γ}{2} - \frac{s}{\tilde{c}} \vert$$

determined for γ=γ_{i,b} where γ is the observation vector [γ_{0,b}, . . . , γ_{N}_{ₛ}_{1,b}] containing a set of correlations, where: 2c²=E{I²} is the variance of the MAI; m is the slope of the tangent; wherein the accumulator determines the sum according to

$$\tilde{Λ} ( γ ) = {\sum }_{i = 0}^{{N}_{s} - 1} {g}_{la} ( {γ}_{i , b} ) ;$$

wherein the threshold function implements a decision rule for binary signalling in detecting the b^{th} symbol according to:

\tilde{Λ}(γ)<0 [symbol] −1 and \tilde{Λ}(γ)>0 [symbol] 1.

### BRIEF DESCRIPTION OF THE DRAWINGS

Embodiments of the invention will now be described with reference to the attached drawings in which:

FIG. 1 is a comparison of the probability density function (PDF) of the MAI component, I, with a Gaussian approximation for (Nᵤ=4) and a Laplacian approximation for (Nᵤ=4);

FIG. 2 is a comparison of the PDF of the MAI component, I, with a Gaussian approximation for Nᵤ=16 and a Laplacian approximation for Nᵤ=16;

FIG. 3 are nonlinearity curves of the Gaussian Laplace Mixture (GLM) detector, gₒₚₜ(γ), for different values of σ, and the Laplacian detector transfer characteristic;

FIG. 4 is a comparison of the BERs of the GLM detector, the Laplacian detector and the conventional linear detector (correlator detector) for Nᵤ=16;

FIG. 5 is a comparison of the BERs of the Simplified Gaussian Laplace Mixture (SGLM) detector, the Laplacian detector and the conventional linear detector (correlator detector) for Nᵤ=16;

FIG. 6 is a comparison of the BERs of the GLM and the SGLM detectors for Nᵤ=16;

FIG. 7 is a block diagram of a receiver provided by an embodiment of the invention; and

FIG. 8 is a flowchart of a method of receiving provided by an embodiment of the invention.

### DETAILED DESCRIPTION OF THE EMBODIMENTS OF THE INVENTION

A novel soft-limiting UWB receiver based on an intuitive assumption that the MAI may be more accurately modeled by a Laplace distribution than a Gaussian distribution was introduced in N. C. Beaulieu and B. Hu, “A soft-limiting receiver structure for time-hopping UWB in multiple access interference,” in Proc. IEEE Int. Symp. Spread Spectr. Techn. Applic., August 2006, hereinafter “Beaulieu et al”. The receiver in Beaulieu et al. yielded better BER performance than conventional correlator receivers for moderate to large SNR. The authors of Beaulieu et al. proposed an adaptive threshold soft-limiting receiver, which is guaranteed to meet or surpass the performance of the correlation receiver. The threshold levels for the adaptive receiver are estimated using numerical computer search.

A soft-limiting receiver is provided that meets or surpasses the performance of the correlation detector under all operating conditions, and is particularly suited to applications where the signal is immersed in a mixture of Laplace and Gaussian noise. In addition, a simplified form of the detector is provided which is much less complex for practical implementation. The performance of the new receivers is compared to the performance of the conventional UWB receiver and the soft-limiting receiver in Beaulieu et al. The new receivers do not require adaptive threshold searches. Simulation results indicate that both new receivers outperform the conventional matched filter UWB receiver for practical UWB applications. The new receivers perform equally well as the soft-limiting receiver in Beaulieu et al. for large values of SNR, and outperform it for small values of SNR.

### System Model

The transmitted signal of the k^{th} user in a TH-UWB system with pulse amplitude modulation (PAM) can be written as

$${s}^{k} ( t ) = \sqrt{{E}_{s} / {N}_{s}} {\sum }_{i = - ∞}^{∞} {d}_{[ i / {N}_{s} ]} p ( t - {iT}_{f} - {c}_{i}^{k} {T}_{c} ) \qquad ( 1 )$$

where p(t) is the transmitted UWB pulse with unit energy, Eₛ is the energy of a symbol, and T_{f} is the length of a frame. One symbol consists of Nₛ pulses and hence a symbol duration is equal to NₛT_{f}. The b^{th} transmitted data symbol is denoted by d_{b} and └x┘ denotes the largest integer not greater than x. The TH sequence is denoted by cᵢ^{k}ε{0, 1, . . . Nₕ}, where the integer Nₕ satisfies the condition NₕT_{c}≦T_{f}, and T_{c} is the TH step size. Note that while the detailed embodiments described herein apply to TH-UWB, the receiver can also be applied to DS-UWB with appropriate modifications. In particular, the partial correlations are performed on the chips of the spreading code and taking into account the polarities of the chips.

Assuming that the system contains Nᵤ active asynchronous users the received signal can be written as

$$r ( t ) = {\sum }_{k = 0}^{{N}_{s} - 1} {h}^{k} {s}^{k} ( t - {τ}^{k} ) + n ( t ) \qquad ( 2 )$$

where h^{k} and τ^{k} are respectively the channel gain and the asynchronous delay of the k^{th} user, and n(t) is additive white Gaussian noise (AWGN) from the channel. The decision statistic of a conventional single user correlation receiver, which uses a template waveform that is matched to the desired users signature waveform with perfect time synchronization, can be written as

$$\begin{matrix}\begin{matrix}{γ}_{b} = {\sum }_{i = {bN}_{s}}^{( b + 1 ) {N}_{s} - 1} {\int }_{{iT}_{f} + {c}_{1}^{0} {T}_{c} + {τ}_{0}}^{( i + 1 ) {T}_{f} + {c}_{i}^{0} {T}_{c} + {τ}_{0}} r ( t ) p ( t - {iT}_{f} - {c}_{i}^{0} {T}_{c} - {τ}_{0} ) d t \\ = {\sum }_{i = {bN}_{s}}^{( b + 1 ) {N}_{s} - 1} {γ}_{i , b} \\ = S + I + n\end{matrix} \\ where , & ( 3 ) \\ {γ}_{i , b} = {\int }_{{iT}_{f} + {c}_{i}^{0} {T}_{c} + {τ}_{0}}^{( i + 1 ) {T}_{f} + {c}_{i}^{0} {T}_{c} + {τ}_{0}} r ( t ) p ( t - {iT}_{f} - {c}_{i}^{0} {T}_{c} - {τ}_{0} ) d t & ( 4 )\end{matrix}$$

and it is assumed that the b^{th} bit of the 0^{th} user is being detected. The signal component S in (3) is given by h⁰d_{b}\sqrt{EₛNₛ} and n denotes the filtered Gaussian noise. The MAI component I can be written as

$$I = {\sum }_{i = {bN}_{s}}^{( b + 1 ) {N}_{s} - 1} {\int }_{{iT}_{f} + {c}_{i}^{0} {T}_{c} + {τ}_{0}}^{( i + 1 ) {T}_{f} + {c}_{i}^{0} {T}_{c} + {τ}_{0}} {\sum }_{k = 1}^{{N}_{a} - 1} {h}^{k} {s}^{k} ( t - {τ}^{k} ) p ( t - {iT}_{f} - {c}_{i}^{0} {T}_{c} - {τ}_{0} ) d t . \qquad ( 5 )$$

Similarly one can express the partial correlation from a single frame, γ_{i,b}, as γ_{i,b}=sᵢ+Iᵢ+nᵢ where sᵢ=s=h^{k}d_{b}\sqrt{Eₛ/Nₛ} since all the Nₛ pulses have equal energy and the channel is assumed constant during a symbol period, and where Iᵢ is given by

$${I}_{i} = {\int }_{{iT}_{f} + {c}_{i}^{0} {T}_{c} + {τ}_{0}}^{( i + 1 ) {T}_{f} + {c}_{i}^{k} {T}_{c} + {τ}_{0}} {\sum }_{k = 1}^{{N}_{a} - 1} {h}^{k} {s}^{k} ( t - {τ}^{k} ) p ( t - {iT}_{f} - {c}_{i}^{0} {T}_{c} - {τ}_{0} ) d t \qquad ( 6 )$$

and E{nᵢ²}=N₀/2 where N₀/2 is the two-sided power spectral density of the AWGN.

### The MAI Component

For the purpose of example, it is assumed that the following pulse shape is employed:

p(t)=(1−16π(t/τₘ)²)exp(−8π(t/τₘ)²) (7)

where τₘ is a parameter controlling the pulse width. More generally, any appropriate pulse shape can be used.

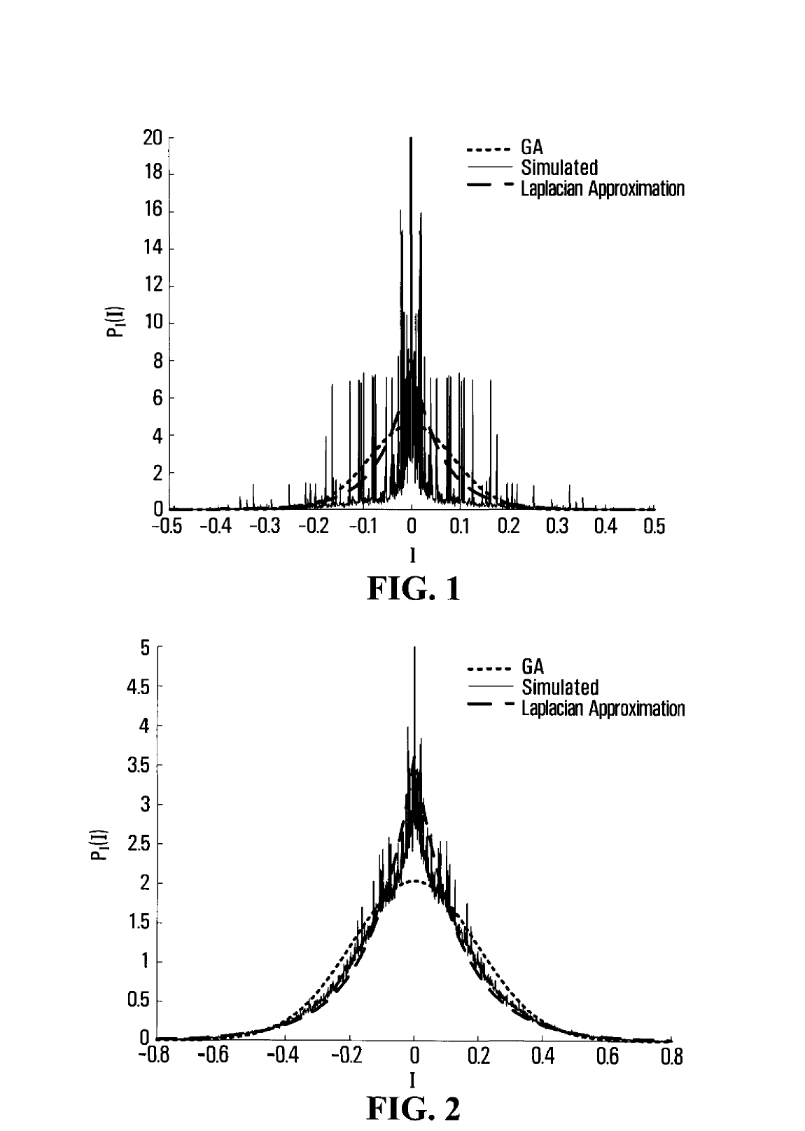

FIG. 1 and FIG. 2 show the probability density function (PDF) of the MAI for 3 (Nᵤ=4) and 15 (Nᵤ=16) equal power interferers, respectively. The distributions of the MAI are generated by simulation and are compared with Gaussian PDFs with the same variance and Laplacian PDFs also with the same variance. The following set of parameters are used in the simulations; Nₛ=8, Nₕ=8 T_{f}=20, T_{c}=0.9, and Nᵤ=4 or 16. The mono-pulse shape used for these simulations is the 2^{nd}-order Gaussian monocycle given by A. R. Forouzan, M. Nasiri-Kenari, and J. A. Salehi, “Performance analysis of time-hopping spread-spectrum multiple-access systems: uncoded and coded schemes,” IEEE Trans. Wireless Commun., vol. 1, pp. 671-681, October 2002.

The vertical lines in the PDF of the MAI correspond to the zeros of

$$\frac{d}{d t} p ( t )$$

and represent singularities in the PDF of the MAI. A GA for the distribution of the MAI is based on a central limit theorem (CLT). The partial MAI components {Iᵢ}ᵢ₌₀^{N}⁻¹ have equal variance and are not mutually independent, but the partial MAI components from different users can be assumed independent since it is assumed that the signalings from the users are independent. If one assumes that all the users are transmitting with equal power, then the MAI is a sum of NₛNᵤ random variables with equal variance which are not all independent. Although one might not expect the CLT to be effective at Nᵤ=4, one might expect its convergence at Nᵤ=16 based on other examples, for example conventional CDMA multiple access systems. However, according to FIG. 2, the CLT is not effective even when the system has a moderate number of interferers. One should note that 15 is not a small number for the number of significant interferers in UWB multiple access systems which operate in a room or other indoor environment. The range of operation of some UWB devices is only a few meters, hence it is highly unlikely to have a large number of significant interferers within a sphere of few meter radius. The reason for the slow convergence of a CLT approximation of the MAI of a UWB system is the fact that an impulse exists at the origin (amplitude=0) in the PDF of the amplitude of a single chip correlator output, and the height of this impulse is equal to 1-(the duty cycle). This problem is exacerbated by the small duty cycle of an UWB signal, which is inevitable in UWB signal design. The duty cycle of a UWB system is given by τₘ/T_{f} where τₘ is the approximate width of a monocycle. The frame length T_{f} is set larger than the maximum delay spread (τ_{d}) of the channel to avoid inter-frame interference (or intra symbol interference). The integer └τ_{d}/τₘ┘ is a large number since the UWB channel contains a large number of resolvable multipath components. Hence the duty cycle τₘ/T_{f} (<τₘ/τ_{d}) is very small. This is in contrast to a CDMA system which has a duty cycle nearly equal to 1 because there is virtually no gap between adjacent chip pulses.

It has been shown that a GA for the MAI underestimates the true BER. If the total interference (noise+interference) has a PDF which is symmetric about the origin, the BER of a constant threshold detector in a binary signaling system with equal energy symbols is directly proportional to the area of a tail region of the PDF of the total interference. Therefore, one surmises that the MAI should have a heavier tail than the Gaussian distribution. The degree of non-Gaussianity of a zero mean PDF is typically measured by its excess kurtosis. For a given noise power, a PDF which has a heavier tail than the Gaussian PDF will have a positive excess kurtosis. Table 1 lists the excess kurtosis values (κₗ) of the MAI (I) for different UWB system parameters where κₗ is given by

$${κ}_{I} = \frac{E [ {I}^{4} ]}{{[ E [ {I}^{2} ] ]}^{2}} - 3. \qquad ( 8 )$$

The results in Table 1 are obtained by simulation. The mono-pulse shape in (7) is used and T_{c}=0.9 in these simulations.

TABLE I
Excess Kurtosis of the MAI

| Nᵤ | Nₕ | Nₛ | T_{f} | k_{I} | k_{I}ᵢ |
|---|---|---|---|---|---|
| 128 | 32 | 8 | 28.8 | 0.1695 | 0.7813 |
| 128 | 16 | 8 | 14.4 | 0.1038 | 0.3885 |
| 25 | 16 | 4 | 20 | 1.1765 | 2.8914 |
| 25 | 8 | 8 | 20 | 1.0027 | 2.4084 |
| 16 | 8 | 8 | 20 | 1.5425 | 3.5577 |
| 16 | 8 | 4 | 20 | 2.0501 | 4.5758 |

In all these cases, one can see that the PDF of MAI is more heavy tailed than the Gaussian PDF. The Laplacian distribution has an excess kurtosis of 3 and has been used to model non-Gaussian impulsive noise distributions. Furthermore, results show that a Laplacian model for the MAI is more accurate than a Gaussian model for a moderate number of users (See N. C. Beaulieu and B. Hu, “A soft-limiting receiver structure for time-hopping UWB in multiple access interference,” in Proc. IEEE Int. Symp. Spread Spectr. Techn. Applic., August 2006 and N. C. Beaulieu and B. Hu, “An adaptive threshold soft-limiting UWB receiver with improved performance in multiuser interference,” in Proc. Int. Conf. Ultra-Wideband, September 2006).

In what follows, the MAI is modeled with the following Laplacian PDF:

$${f}_{I} ( I ) = \frac{1}{2 c} exp ( - \frac{\vert I \vert}{c} ) \qquad ( 9 )$$

where 2c²=E{I²} is the variance of the MAI.
Table I also shows the excess kurtosis κₗ, of the partial MAI components Iᵢ. The values of kurtosis, κ_{I}_{ᵢ}, given in Table 1 support the choice of the Laplacian model for Iᵢ as well.

### New Receiver Structure

Based on employing the Laplacian model for the MAI, the detection problem now becomes the detection of a known signal in a mixture of Gaussian and Laplacian noise. It is assumed that the detection problem has Nₛ observations per symbol, which are the partial correlations {γ_{i,b} (=s+Iᵢ+nᵢ)}ᵢ₌₀^{N}^{ₛ}⁻¹. Using the Laplacian model, the distribution of Iᵢ can be written as exp(−|Iᵢ|/cᵢ)/2cᵢ and the distribution of nᵢ is given by exp(−nᵢ²/2σᵢ²)/\sqrt{2π}σᵢ where 2cᵢ²=2(\tilde{c})²=E{Iᵢ²} and σᵢ²=σ²=E{nᵢ²}=N₀/2. Since Iᵢ and nᵢ are independent, the distribution of the sum Iᵢ+nᵢ can be found by convolving the distributions of the summands. The result is given by

$${f}_{{v}_{i}} ( {v}_{i} ) = \frac{exp ( {σ}^{2} / 2 {\tilde{c}}^{2} )}{ 2 \tilde{c}} [ exp ( \frac{{v}_{i}}{\tilde{c}} ) Q ( \frac{{v}_{i}}{σ} + \frac{σ}{\tilde{c}} ) + exp ( - \frac{{v}_{i}}{\tilde{c}} ) Q ( - \frac{{v}_{i}}{σ} + \frac{σ}{\tilde{c}} ) ] \qquad ( 10 )$$

where νᵢ=Iᵢ+nᵢ and Q(·) is the standard Gaussian Q-function. For simplicity, it is assumed that the observations γ_{i,b} are independent. Based on the set of Nₛ observations, an optimum receiver (the maximum likelihood receiver) can be derived. The log-likelihood function for the binary detection of equiprobable data symbols with the set of observations, γ, is given by the sum of the partial decision statistics gₒₚₜ(γ_{i,b}) according to

$$Λ ( γ ) = {\sum }_{i = 0}^{{N}_{s} - 1} {g}_{opt} ( {γ}_{i , b} ) \qquad ( 11 )$$

where gₒₚₜ(γ), which is known as the nonlinearity function, is given by

$${g}_{opt} ( γ ) = ln [ \frac{\begin{matrix}exp ( \frac{γ - s}{\tilde{c}} ) Q ( \frac{γ - s + {σ}^{2} / \tilde{c}}{σ} ) + \\ exp ( - \frac{γ - s}{\tilde{c}} ) Q ( \frac{- γ + s + {σ}^{2} / \tilde{c}}{σ} )\end{matrix}}{\begin{matrix}exp ( \frac{γ + s}{\tilde{c}} ) Q ( \frac{γ + s + {σ}^{2} / \tilde{c}}{σ} ) + \\ exp ( - \frac{γ + s}{\tilde{c}} ) Q ( \frac{- γ - s + {σ}^{2} / \tilde{c}}{σ} )\end{matrix}} ] \qquad ( 12 )$$

and γ is the observation vector [γ_{0,b}, . . . , γ_{N}_{ₛ}_{=1,b}]. The decision rule for binary signalling in detecting the b^{th} symbol is given by

Λ(γ)<0 [symbol] −1 and Λ(γ)>0 [symbol] 1. (13)

Eqs. (11)-(13) define an optimal, maximum likelihood (ML), receiver for a binary antipodal signaling scheme when the interference-plus-noise samples have the PDF in (10). This receiver is not optimal for the UWB system considered here because the Laplacian PDF in (9) is an approximation to the true PDF of the MAI. However this receiver, which we will call the Gaussian Laplace mixture (GLM) receiver, outperforms the conventional matched filter UWB receiver and the soft-limiting receiver in Beaulieu et al., at least in the examples considered below.

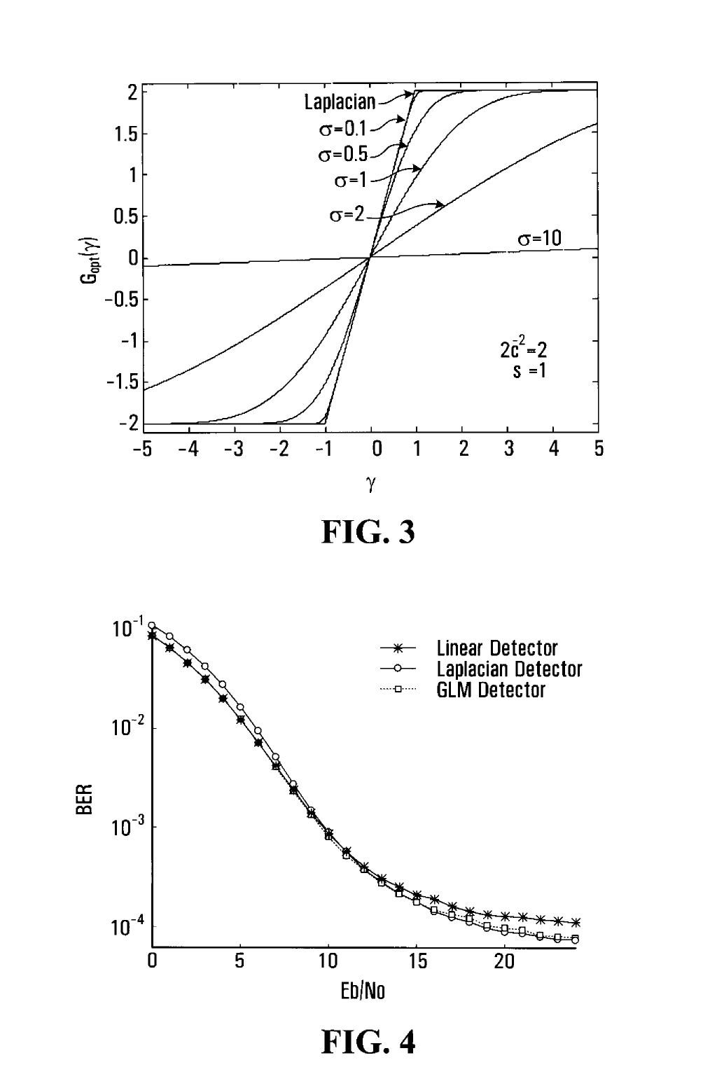

FIG. 3 shows the optimum nonlinearities for different values of σ. The variance of the partial MAI, Iᵢ, 2\tilde{c}² is fixed and is equal to 2, and s=1. Note that, for a given set of system parameters, \tilde{c} is a constant. One can show that

$${lim}_{v -> ∞} {g}_{opt} ( γ ) = 2 s / \tilde{c} and {lim}_{v -> - ∞} {g}_{opt} ( γ ) = 2 s / \tilde{c} .$$

Therefore, the horizontal lines gₒₚₜ(γ)=2s/\tilde{c} and gₒₚₜ(γ)=−2s/\tilde{c} are asymptotes to the optimum nonlinearity function gₒₚₜ(γ). The slope of the nonlinearity curve decreases with increasing σ and the curve becomes nearly a straight line, within the range of γ of interest, when σ becomes large. On the other hand, when σ is close to zero the nonlinearity curve approaches the Laplacian detector nonlinearity N. C. Beaulieu and S. Niranjayan, “New UWB Receiver Designs based on a Gaussian-Laplacian Noise-Plus-Mai Model,” IEEE International Conference on Communications (ICC 2007), Glasgow, Scotland, pp. 4128-4133, Jun. 24-28, 2007.

### Simplified Receiver

According to an embodiment of the invention a simplified receiver is provided that makes use of a close approximation to the nonlinearity function by another simple function. To derive a simplified detector, the nonlinearity curve, gₒₚₜ(γ), is approximated as

$${g}_{la} ( γ ) = \{ \begin{matrix}tanget of {g}_{opt} ( γ ) at the origin , & for \vert {g}_{opt} ( γ ) \vert \leq 2 s / \tilde{c} \\ 2 s / \tilde{c} , & for {g}_{opt} ( γ ) > 2 s / \tilde{c} \\ - 2 s / \tilde{c} , & for {g}_{opt} ( γ ) < - 2 s / \tilde{c} .\end{matrix} \qquad ( 14 )$$

The slope of the nonlinearity function at the origin is given by

$$\frac{d}{d γ} ln [ \frac{{f}_{v} ( γ - s )}{{f}_{v} ( γ + s )} ] {\vert}_{γ = 0} = \frac{{f}_{γ}^{′} ( - s )}{{f}_{γ} ( - s )} - \frac{{f}_{γ}^{′} ( s )}{{f}_{γ} ( s )} . \qquad ( 15 )$$

where f_{γ}(·)=f_{γ}_{ᵢ}(·) for all i. Since f_{γ}(s)=f_{γ}(−s) and f′_{γ}(s)=−f′_{γ}(−s) the slope is given by

$$m = \frac{d}{d γ} ln [ \frac{{f}_{γ} ( γ - s )}{{f}_{γ} ( γ + s )} ] {\vert}_{γ = 0} = \frac{2 {f}_{γ}^{′} ( - s )}{{f}_{γ} ( s )} . \qquad ( 16 )$$

The approximate nonlinearity function gₗₐ(γ) is given by

$${g}_{la} ( γ ) = \vert \frac{m γ}{2} + \frac{s}{\tilde{c}} \vert - \vert \frac{m γ}{2} - \frac{s}{\tilde{c}} \vert . \qquad ( 17 )$$

The decision variable of the simplified receiver for the detection of the b^{th} symbol is calculated as the sum of the partial decision statistics gₗₐ(γ_{i,b}) according to

$$\tilde{Λ} ( γ ) = {\sum }_{i = 0}^{{N}_{s} - 1} {g}_{la} ( {γ}_{i , b} ) \qquad ( 18 )$$

and then the decision rule is given by

\tilde{Λ}(γ)<0 [symbol] −1 and \tilde{Λ}(γ)>0 [symbol] 1.

This simplified receiver defined by Eqs. (16)-(18) will be referred to as the simplified Gaussian Laplace mixture (SGLM) receiver. The nonlinear function (17) is similar to the soft-limiter in Beaulieu et al. except that the slope in the linear region is different. For the SGLM receiver, the slope (m) is a function of SIR and SNR. For the soft-limiting receiver, the slope is always equal to 2/\tilde{c}. Note that the soft-limiting (Laplacian) receiver derived in Beaulieu et al. can be obtained by setting m=2/\tilde{c} in the SGLM receiver. Furthermore, when σ→0, the limiting value of m will be 2/\tilde{c} and this represents a Laplacian detector.

The SGLM amounts to a piecewise linear approximation to the GLM receiver, with three linear segments. Other approximations to the GLM receiver are also contemplated. For example, in some embodiments a piecewise linear approximation to the GLM is employed that may have more than three linear segments.

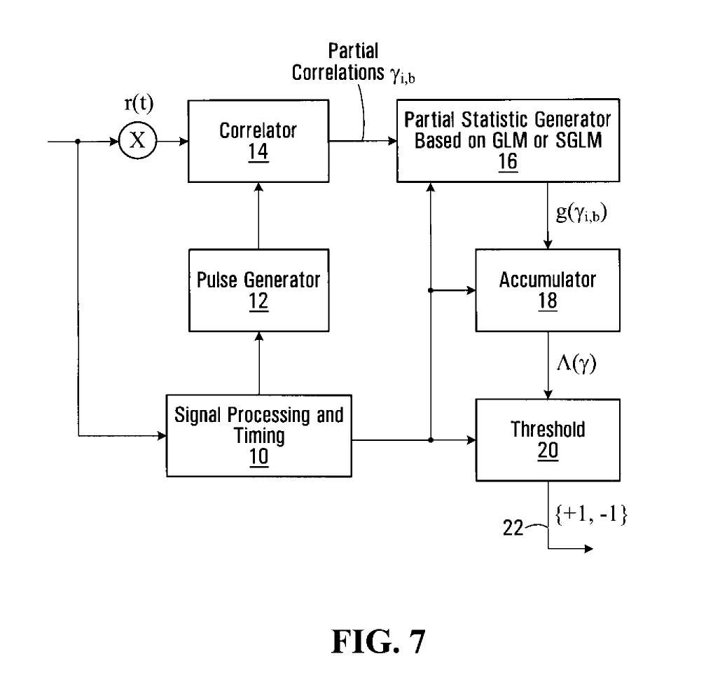

A block diagram showing an example implementation of a Gaussian noise plus Laplacian MAI receiver is shown in FIG. 7. The receiver has signal processing and timing function 10, pulse generator 12, and correlator 14 operatively coupled together in sequence. The output of the correlator 14 is a set of observations (partial correlations νᵢ) that is input to a partial statistic generator 16 based on a Gaussian noise plus Laplacian MAI channel assumption. The partial statistic generator 16 produces the partial statistics g(γ_{i,b}), that are passed to an accumulator 18 where they are accumulated to produce the overall decision statistic Λ(γ). This is then processed by threshold function 20 to produce an output 22. The partial statistic generator 16, accumulator 18, and threshold function 20 are also operatively coupled to the signal processing and timing function 10. The partial statistics may be based on the optimal model or a piecewise linear approximation to the optimal model.

In operation a received signal r(t) is processed by signal processing and timing function 10 to recover timing. In a specific implementation, the timing of partial statistics is used by the partial statistic generator 16 and the accumulator 18; the timing of the overall decision statistic is used by the partial statistic generator 16, the accumulator 18 and the threshold function 20. In some embodiments, the signal processing and timing function 10 also determines one, or a combination of values for s, \tilde{c}, m and σ. These values can be determined in any appropriate manner and are fed to the partial statistic generator 16 for use in determining the partial statistics. Specific examples include channel estimation, table look-up, and hard-coded values that may involve a performance compromise.

As a function of this timing, the pulse generator 12 generates a pulse for use by correlator 14 in performing a correlation between the pulse and r(t). The output γ_{i,b} of the correlator 14 is passed to the partial statistic generator 16 to produce the partial statistic g(γ_{i,b}) using equation (17). The g(γ_{i,b})'s relating to the same symbol are summed in the accumulator 18 to produce Λ(γ), and a final decision on the sum is made by the threshold function 20.

The components of FIG. 7 can be implemented in one or a combination of software (such as DSP code), hardware, and firmware to name a few specific examples. In some embodiments, there is at least one antenna (not shown) through which to receive the signal r(t).

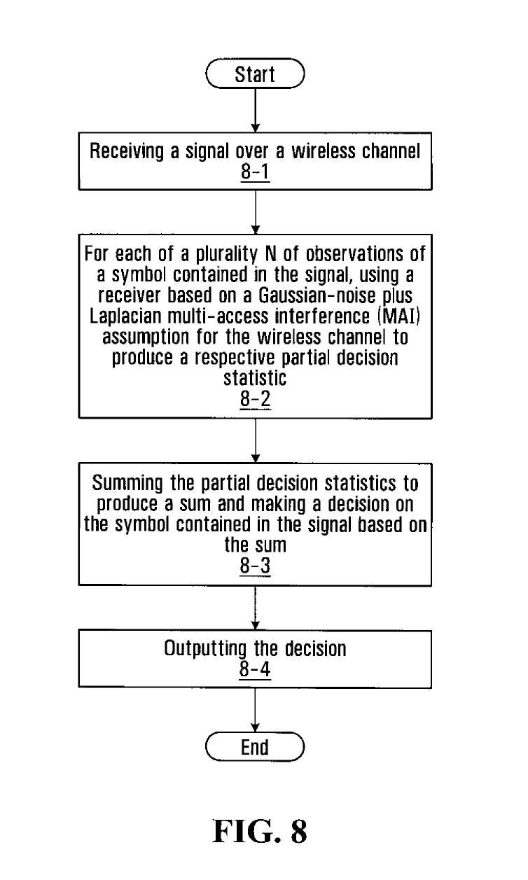

A flowchart of a method of receiving provided by an embodiment of the invention is shown in FIG. 8. The method begins at step 8-1 with receiving a signal over a wireless channel. The method continues at step 8-2 with for each of a plurality N of observations of a symbol contained in the signal, using a receiver based on a Gaussian-noise plus Laplacian multi-access interference (MAI) assumption for the wireless channel to produce a respective partial decision statistic. The method continues at step 8-3 with summing the partial decision statistics to produce a sum and making a decision on the symbol contained in the signal based on the sum. Finally, a decision is output at step 8-4.

### Numerical Results

The BER performances of the new detectors are evaluated by simulation and compared with the BER performance of a conventional correlation detector (linear detector). Unless stated otherwise, the system parameters used in these simulations are the same as those used above. In FIG. 4, the BER performance of the GLM detector, the linear detector and the Laplacian detector are compared. The Laplacian detector outperforms the linear detector for medium to large SNR values while underperforming the linear detector for small to medium SNR values. Observe that the performance of the GLM detector is very close to that of the linear detector in the small SNR region and is very close to that of the Laplacian detector in the medium to large SNR region. This is because the GLM detector becomes a linear detector at small SNR values and it approaches a Laplacian detector as the SNR value becomes large.

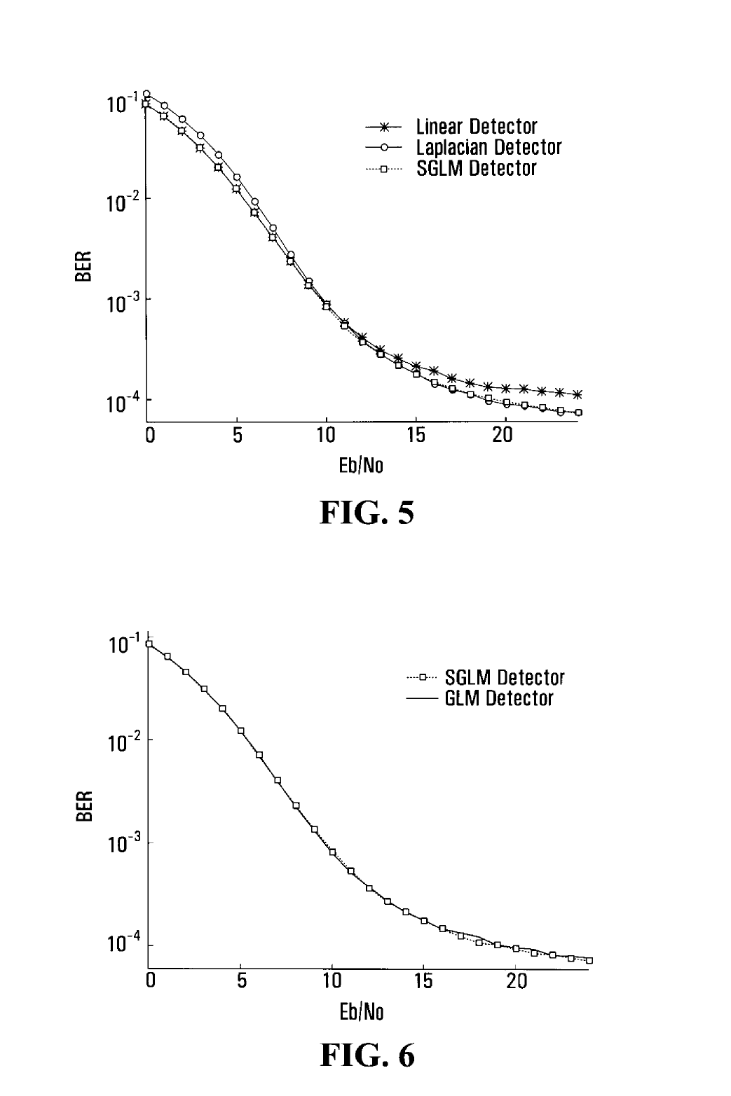

FIG. 5 shows a comparison of the BER performances of the SGLM detector with the linear and Laplacian detectors. The BER performance of the SGLM detector always meets or surpasses that of the linear detector or the Laplacian detector. FIG. 6 shows that it closely approximates the BER performance of the GLM detector; the two curves in FIG. 6 are substantially graphically coincident. Note that the implementation of the SGLM detector is much simpler than that of the GLM detector. The SGLM receiver needs only to evaluate the slope m at a given SNR, which can be calculated and pre-wired into the receiver implementation. Finally, as an example, at SNR=16 dB, the GLM detector and the SGLM detector are around 2 dB (in SNR) better in BER performance than the linear detector in the examples. Note that this accounts for approximately 37% reduction in the average transmitted power which is significant with UWB devices which are expected to operate with very low power.

Note that while the detailed embodiments described herein apply to TH-UWB, the receiver structure can also be applied to DS-UWB with appropriate modifications.

The detailed examples above assume the new receiver approaches are applied to the reception of a UWB signal. In some embodiments, the UWB signals are as defined in the literature to be any signal having a signal bandwidth that is greater than 20% of the carrier frequency, or a signal having a signal bandwidth greater than 500 MHz. In some embodiments, the receiver approach is applied to signals having a signal bandwidth greater than 15% of the carrier frequency. In some embodiments, the receiver approach is applied to signals having pulses that are 1 ns in duration or shorter. These applications are not exhaustive nor are they mutually exclusive. For example, most UWB signals satisfying the literature definition will also feature pulses that are 1 ns in duration or shorter.

More generally, in some embodiments the receiver approach is applied to signals for which a plurality of correlations need to be performed in a receiver. In a specific example, the method is applied for a plurality of correlations determined by the repetition code in a UWB receiver. In other applications, the method is applied for a plurality of correlations in a Rake receiver or a finger of a Rake receiver. That is to say, the correlations might be used across signal chips of a repetition code, across the signal chips of a code division multiple access (CDMA) spreading code, across the fingers of a Rake receiver, or the new receiver might be used as a unit in each finger of a Rake receiver.

Numerous modifications and variations of the present invention are possible in light of the above teachings. It is therefore to be understood that within the scope of the appended claims, the invention may be practiced otherwise than as specifically described herein.

We claim:

1. A method of receiving comprising:
receiving a signal over a wireless channel;
for each of a plurality N of observations of a symbol contained in the signal, using a receiver based on a Gaussian-noise plus Laplacian multi-access interference (MAI) assumption for the wireless channel to produce a respective partial decision statistic;
summing the partial decision statistics to produce a sum and making a decision on the symbol contained in the signal based on the sum;
outputting the decision.

2. The method of claim 1 wherein
for each of a plurality N of observations of a symbol contained in the signal, using a receiver based on a Gaussian-noise plus Laplacian multi-access interference (MAI) assumption for the wireless channel to produce a respective partial decision statistic comprises:
using a receiver model that is optimal based on the Gaussian noise plus Laplacian MAI assumption for the wireless channel.

3. The method of claim 1 wherein
for each of a plurality N of observations of a symbol contained in the signal, using a receiver based on a Gaussian-noise plus Laplacian multi-access interference (MAI) assumption for the wireless channel to produce a respective partial decision statistic comprises:
using a piecewise linear approximation to a receiver model that is optimal based on the Gaussian noise plus Laplacian MAI assumption for the wireless channel.

4. The method of claim 3 wherein using a piecewise linear approximation comprises:
using a first limit value of the optimal receiver model above a first threshold;
using a second limit value of the optimal receiver below a second threshold;
using a straight line tangent to the optimal receiver at the origin between the first threshold and the second threshold.

5. The method of claim 1 wherein receiving a signal comprises receiving a signal having a signal bandwidth that is greater than 20% of the carrier frequency, or receiving a signal having a signal bandwidth greater than 500 MHz.

6. The method of claim 1 wherein receiving a signal comprises receiving a signal having a signal bandwidth greater than 15% of the carrier frequency.

7. The method of claim 1 wherein receiving a signal comprises receiving a signal having pulses that are 1 ns in duration or shorter.

8. The method of claim 1 wherein receiving a signal comprises receiving a UWB signal.

9. The method of claim 1 wherein receiving a signal comprises receiving a TH UWB signal.

10. The method of claim 1 wherein receiving a signal comprises receiving a DS UWB signal.

11. The method of claim 1 further comprising:
determining the plurality N of observations by determining an observation vector [γ_{0,b}, . . . , γ_{N}_{ₛ}_{-1,b}] containing a set of correlations;
wherein each partial decision statistic is gₒₚₜ(γ_{i,b}) and is determined according to
$${g}_{opt} ( γ ) = ln [ \frac{\begin{matrix}exp ( \frac{γ - s}{\tilde{c}} ) Q ( \frac{γ - s + {σ}^{2} / \tilde{c}}{σ} ) + \\ exp ( - \frac{γ - s}{\tilde{c}} ) Q ( \frac{- γ + s + {σ}^{2} / \tilde{c}}{σ} )\end{matrix}}{\begin{matrix}exp ( \frac{γ + s}{\tilde{c}} ) Q ( \frac{γ + s + {σ}^{2} / \tilde{c}}{σ} ) + \\ exp ( - \frac{γ + s}{\tilde{c}} ) Q ( \frac{- γ - s + {σ}^{2} / \tilde{c}}{σ} )\end{matrix}} ]$$
determined for γ=γ_{i,b} of the observation vector [γ_{0,b}, . . . , γ_{N}_{ₛ}_{-1,b}] where:
σᵢ²=σ²=E{nᵢ²}=N₀/2, is the noise variance, 2\tilde{c}²=E{I²} is the variance of the MAI;
Q(·) is the standard Gaussian Q-function;
s is a desired signal component at the receiver;
and wherein the sum is determined according to
$$Λ ( γ ) = {\sum }_{i = 0}^{{N}_{s} - 1} {g}_{opt} ( {γ}_{i , b} )$$
and the decision rule for binary signalling in detecting the b^{th} symbol is given by
Λ(γ)<0 [symbol] −1 and Λ(γ)>0 [symbol] 1.

12. The method of claim 4 further comprising:
determining the plurality N of observations by determining an observation vector containing a set of correlations;
wherein each partial decision statistic is gₗₐ(γ_{i,b}) and is determined according to
$${g}_{la} ( γ ) = \vert \frac{m γ}{2} + \frac{s}{\tilde{c}} \vert - \vert \frac{m γ}{2} - \frac{s}{\tilde{c}} \vert$$
determined for γ=γ_{i,b} of the observation vector [γ_{0,b}, . . . , γ_{N}_{ₛ}_{-1,b}] where:
2\tilde{c}₂=E{I²} is the variance of the MAI;
m is the slope of the tangent;
and wherein the sum is determined according to
$$\tilde{Λ} ( γ ) = {\sum }_{i = 0}^{{N}_{s} - 1} {g}_{la} ( {γ}_{i , b} )$$
and the decision rule for binary signalling in detecting the b^{th} symbol is given by
\tilde{Λ}(γ)<0 [symbol] −1 and \tilde{Λ}(γ)>0 [symbol] 1.

13. An apparatus comprising:
a correlator that generates a plurality of partial correlations from a signal;
a partial statistic generator that generates a respective partial statistic for each partial correlation based on a Gaussian-noise plus Laplacian multi-access interference (MAI) assumption for the wireless channel to produce a respective partial decision statistic;
an accumulator that accumulates the partial statistics to produce a sum;
a threshold function that makes a decision based on the sum and outputs the decision.

14. The apparatus of claim 13 wherein the partial statistic generator generates the respective partial statistic using an optimal nonlinearity function.

15. The apparatus of claim 13 wherein the partial statistic generator generates the respective partial statistic using a nonlinearity function that is a piecewise approximation to an optimal nonlinearity function.

16. The apparatus of claim 15 wherein the partial statistic generator is configured to use a piecewise approximation by:
using a first limit value of the optimal receiver model above a first threshold;
using a second limit value of the optimal receiver below a second threshold;
using a straight line tangent to the optimal receiver at the origin between the first threshold and the second threshold.

17. The apparatus of claim 14 wherein the partial statistic generator generates each partial decision statistic gₒₚₜ(γ_{i,b}) and is determined according to
$${g}_{opt} ( γ ) = ln [ \frac{\begin{matrix}exp ( \frac{γ - s}{\tilde{c}} ) Q ( \frac{γ - s + {σ}^{2} / \tilde{c}}{σ} ) + \\ exp ( - \frac{γ - s}{\tilde{c}} ) Q ( \frac{- γ + s + {σ}^{2} / \tilde{c}}{σ} )\end{matrix}}{\begin{matrix}exp ( \frac{γ + s}{\tilde{c}} ) Q ( \frac{γ + s + {σ}^{2} / \tilde{c}}{σ} ) + \\ exp ( - \frac{γ + s}{\tilde{c}} ) Q ( \frac{- γ - s + {σ}^{2} / \tilde{c}}{σ} )\end{matrix}} ]$$
determined for γ=γ_{i,b} where γ is the observation vector [γ_{0,b}, . . . , γ_{N}_{ₛ}_{-1,b}] containing a set of correlations, where:
σᵢ²=σ²=E{nᵢ²}=N₀/2, is the noise variance, 2c²=E{I²} is the variance of the MAI;
Q(·) is the standard Gaussian Q-function;
s is a desired signal component at the receiver;
wherein the accumulator determines the sum according to
$$Λ ( γ ) = {\sum }_{i = 0}^{{N}_{s} - 1} {g}_{opt} ( {γ}_{i , b} ) ;$$
and wherein the threshold function implements a decision rule for binary signalling in detecting the b^{th} symbol according to
Λ(γ)<0 [symbol] −1 and Λ(γ)>0 [symbol] 1.

18. The apparatus of claim 15 wherein the partial statistic generator generates each partial decision statistic gₗₐ(γ_{i,b}) according to
$${g}_{la} ( γ ) = \vert \frac{m γ}{2} + \frac{s}{\tilde{c}} \vert - \vert \frac{m γ}{2} - \frac{s}{\tilde{c}} \vert$$
determined for γ=γ_{i,b} where γ is the observation vector [γ_{0,b}, . . . , γ_{N}_{ₛ}_{-1,b}] containing a set of correlations, where:
2\tilde{c}²=E{I²} is the variance of the MAI;
m is the slope of the tangent;
wherein the accumulator determines the sum according to
$$\tilde{Λ} ( γ ) = {\sum }_{i = 0}^{{N}_{s} - 1} {g}_{la} ( {γ}_{i , b} ) ;$$
wherein the threshold function implements a decision rule for binary signalling in detecting the b^{th} symbol according to:
\tilde{Λ}(γ)<0 [symbol] −1 and \tilde{Λ}(γ)>0 [symbol] 1.

19. The apparatus of claim 13 further comprising:
a signal processing and timing function configured to determine at least one of:
timing information, s, \tilde{c}, m and σ.

20. The apparatus of claim 13 further comprising:
at least one antenna for receiving the signal over a wireless channel.
